(19) United States
(12) Patent Application Publication
(10) Pub. No.: US 2025/0273612 A1
(43) Pub. Date: Aug. 28, 2025

(54) PACKAGE COMPRISING A SUBSTRATE INCLUDING AN INTER SUBSTRATE INTERCONNECT STRUCTURE COMPRISING AN INNER INTERCONNECT

(71) Applicant: QUALCOMM Incorporated, San Diego, CA (US)

(72) Inventors: Aniket PATIL, San Diego, CA (US); Joan Rey Villarba BUOT, Escondido, CA (US); Manuel ALDRETE, Encinitas, CA (US)

(21) Appl. No.: 18/589,596

(22) Filed: Feb. 28, 2024

(51) Int. Cl. H01L 23/00; H01L 23/31; H01L 23/498; H01L 25/065

(52) U.S. Cl. CPC H01L 24/13; H01L 23/3128; H01L 23/49816; H01L 24/05; H01L 25/0657; H01L 2224/05009; H01L 2224/05025; H01L 2224/13013; H01L 2224/13025; H01L 2225/06513; H01L 2225/06517; H01L 2924/01013; H01L 2924/01028; H01L 2924/01029; H01L 2924/0105; H01L 2924/15311; H01L 2924/182

(57) ABSTRACT

A package comprising a first substrate; an integrated device coupled to the first substrate through at least a first plurality of solder interconnects; an inter substrate interconnect structure coupled to the first substrate through at least a second plurality of solder interconnects. The inter substrate interconnect structure comprises an inner interconnect; a dielectric layer coupled to the inner interconnect; and an interconnect coupled to the dielectric layer, wherein the interconnect surrounds the dielectric layer and the inner interconnect; a second substrate coupled to the inter substrate interconnect structure through at least a third plurality of solder interconnects; and an encapsulation layer coupled to the first substrate and the second substrate.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a first substrate; an integrated device coupled to the first substrate through at least a first plurality of solder interconnects; an inter substrate interconnect structure coupled to the first substrate through at least a second plurality of solder interconnects. The inter substrate interconnect structure comprises an inner interconnect; a dielectric layer coupled to the inner interconnect; and an interconnect coupled to the dielectric layer, wherein the interconnect surrounds the dielectric layer and the inner interconnect; a second substrate coupled to the inter substrate interconnect structure through at least a third plurality of solder interconnects; and an encapsulation layer coupled to the first substrate and the second substrate.

Another example provides a method for fabricating a package. The method provides a first substrate. The method couples an integrated device to the first substrate through at least a first plurality of solder interconnects. The method couples an inter substrate interconnect structure to the first substrate through at least a second plurality of solder interconnects. The inter substrate interconnect structure comprises an inner interconnect; a dielectric layer coupled to the inner interconnect; and an interconnect coupled to the dielectric layer, wherein the interconnect surrounds the dielectric layer and the inner interconnect. The method couples a second substrate to the inter substrate interconnect structure through at least a third plurality of solder interconnects. The method forms an encapsulation layer between the first substrate and the second substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes substrates, integrated devices and inter substrate interconnect structures.

FIG. 2 illustrates an exemplary cross sectional profile view of a substrate comprising an inter substrate interconnect structure.

FIG. 3 illustrates an exemplary view of an inter substrate interconnect structure comprising a wire.

FIG. 4 illustrates an exemplary view of an inter substrate interconnect structure comprising a wire.

FIG. 5 illustrates an exemplary view of an inter substrate interconnect structure comprising a wire.

FIG. 6 illustrates an exemplary cross sectional profile view of a package that includes substrates, integrated devices and inter substrate interconnect structures.

FIG. 7 illustrates an exemplary cross sectional profile view of a substrate comprising an inter substrate interconnect structure.

FIG. 8 illustrates an exemplary view of an inter substrate interconnect structure comprising a wire.

FIG. 9 illustrates an exemplary view of an inter substrate interconnect structure comprising a wire.

FIG. 10 illustrates an exemplary view of an inter substrate interconnect structure comprising a wire.

FIG. 11 illustrates an exemplary cross sectional plan view of a substrate comprising an inter substrate interconnect structure.

FIG. 12 illustrates an exemplary sequence for fabricating an inter substrate interconnect structure comprising a wire.

FIG. 13 illustrates an exemplary flow chart of a method for fabricating an inter substrate interconnect structure comprising a wire.

FIGS. 14A-14D illustrate an exemplary sequence for fabricating a package that includes substrates, integrated devices and inter substrate interconnect structures.

FIG. 15 illustrates an exemplary flow chart of a method for fabricating a package that includes substrates, integrated devices and inter substrate interconnect structures.

FIGS. 16A-16B illustrate an exemplary sequence for fabricating a substrate.

FIG. 17 illustrates an exemplary flow chart of a method for fabricating a substrate.

FIG. 18 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure a package comprising a first substrate; an integrated device coupled to the first substrate through at least a first plurality of solder interconnects; an inter substrate interconnect structure coupled to the first substrate through at least a second plurality of solder interconnects. The inter substrate interconnect structure comprises an inner interconnect; a dielectric layer coupled to the inner interconnect; and an interconnect coupled to the dielectric layer, wherein the interconnect surrounds the dielectric layer and the inner interconnect; a second substrate coupled to the inter substrate interconnect structure through at least a third plurality of solder interconnects; and an encapsulation layer coupled to the first substrate and the second substrate. The use of the inter substrate interconnect structure helps provide high density interconnects between substrates, which can help improve the performance of the integrated devices and/or the package.

### Exemplary Package Comprising Inter Substrate Interconnect Structures Comprising an Inner Interconnect

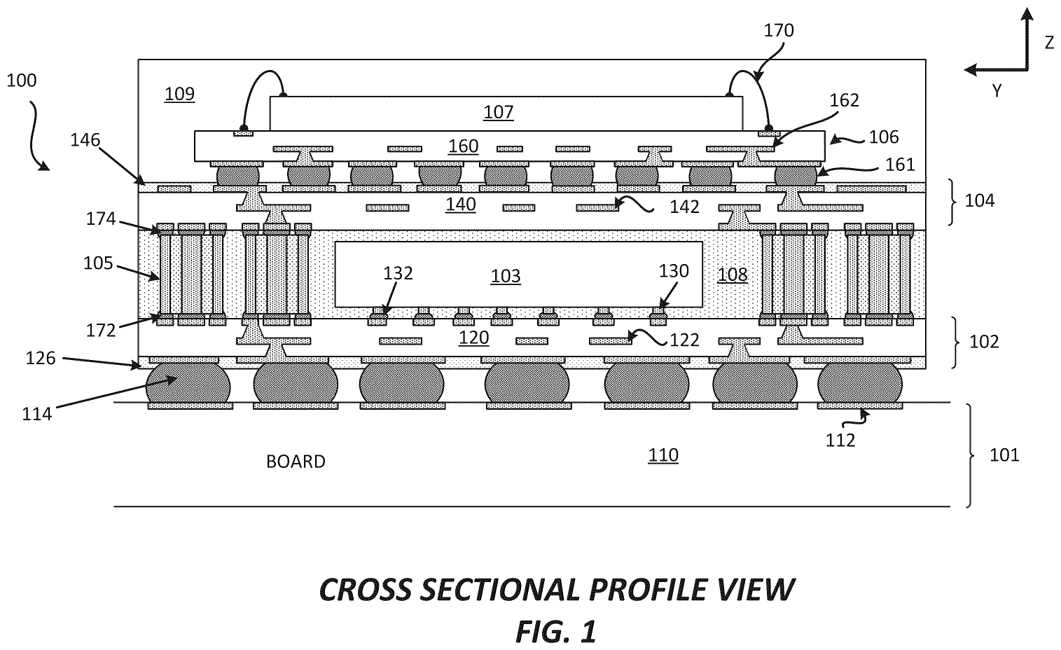

FIG. 1 illustrates a cross sectional profile view of a package 100 that includes inter substrate interconnect structures comprising a wire. The package 100 may be implemented as part of a package on package (POP). The package 100 is coupled to a board 101 through a plurality of solder interconnects 114. The board 101 includes at least one board dielectric layer 110 and a plurality of board interconnects 112. The board 101 may include a printed circuit board (PCB).

The package 100 includes a substrate 102, an integrated device 103, a substrate 104, a substrate 106, an integrated device 107, an encapsulation layer 108, an encapsulation layer 109 and a plurality of inter substrate interconnect structures 105. As will be further described below, each of inter substrate interconnect structures 105 may include an inner interconnect (e.g., a wire) and an outer interconnect.

The integrated device 103 is coupled to the substrate 102 through at least a plurality of solder interconnects 132. For example, the integrated device 103 is coupled to a plurality of interconnects 121 of the substrate 102 through a plurality of pillar interconnects 130 and/or a plurality of solder interconnects 132. The substrate 102 includes a dielectric layer 120, a plurality of interconnects 122 and a solder resist layer 126. The substrate 102 is coupled to the board 101 through the plurality of solder interconnects 114.

The plurality of inter substrate interconnect structures 105 are coupled to the plurality of interconnects 122 of the substrate 102 through a plurality of solder interconnects 172. The substrate 104 is coupled to the plurality of inter substrate interconnect structures 105 through a plurality of solder interconnects 174. The substrate 104 is coupled to the substrate 102 through the plurality of inter substrate interconnect structures 105. The encapsulation layer 108 is located between the substrate 102 and the substrate 104. The encapsulation layer 108 is coupled to the substrate 102 and the substrate 104. The encapsulation layer 108 may at least partially encapsulate the integrated device 103 and the plurality of inter substrate interconnect structures 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The substrate 104 includes a dielectric layer 140, a plurality of interconnects 142 and a solder resist layer 146. The substrate 106 includes a dielectric layer 160 and a plurality of interconnects 162. The substrate 106 is coupled to the substrate 104 through a plurality of solder interconnects 161. The integrated device 107 may be mechanically coupled to the substrate 106. An adhesive may be used to mechanically couple the integrated device 107 to the substrate 106. A plurality of wire bonds 170 are coupled to the integrated device 107 and the substrate 106. The plurality of wire bonds 170 may be coupled to pads of the integrated device 107 and the plurality of interconnects 162 of the substrate 106. The plurality of wire bonds 170 may be configured to provide electrical paths between the integrated device 107 and the substrate 106. The plurality of wire bonds 170 may include wires.

The encapsulation layer 109 may be coupled to a surface of the substrate 104. The encapsulation layer 109 may at least partially encapsulate the substrate 106, the integrated device 107 and the plurality of wire bonds 170. The encapsulation layer 109 may include a mold, a resin and/or an epoxy. The encapsulation layer 109 may be a means for encapsulation. The encapsulation layer 109 may be similar to the encapsulation layer 108. The encapsulation layer 109 may be provided by using a compression and transfer molding process, a sheet molding process, or a liquid molding process.

Each inter substrate interconnect structure from the plurality of inter substrate interconnect structures 105 may be configured to provide a first electrical path and a second electrical path. Each inter substrate interconnect from the plurality of inter substrate interconnect structures 105 may be an inter substrate concentric interconnect structure. Each inter substrate interconnect from the plurality of inter substrate interconnect structures 105 may be an inter substrate coaxial interconnect structure.

A first electrical path between the integrated device 107 and the board 101 may include (i) a first wire bond from the plurality of wire bonds 170, (ii) a first plurality of interconnects from the plurality of interconnects 162, (iii) a first solder interconnect from the plurality of solder interconnects 161, (iv) a first plurality of interconnects from the plurality of interconnects 142, (v) a first solder interconnect from the plurality of solder interconnects 174, (vi) an inner interconnect (e.g., wire) from an inter substrate interconnect structure (e.g., 105), (vii) a first solder interconnect from the plurality of solder interconnects 172, (viii) a first plurality of interconnects from the plurality of interconnects 122, (ix) a first solder interconnect from the plurality of solder interconnects 114, and/or (x) a first board interconnect from the plurality of board interconnects 112.

A second electrical path between the integrated device 107 and the board 101 may include (i) a second wire bond from the plurality of wire bonds 170, (ii) a second plurality of interconnects from the plurality of interconnects 162, (iii) a second solder interconnect from the plurality of solder interconnects 161, (iv) a second plurality of interconnects from the plurality of interconnects 142, (v) a second solder interconnect from the plurality of solder interconnects 174, (vi) an outer interconnect (e.g., a non-wire interconnect) from an inter substrate interconnect structure (e.g., 105), (vii) a second solder interconnect from the plurality of solder interconnects 172, (viii) a second plurality of interconnects from the plurality of interconnects 122, (ix) a second solder interconnect from the plurality of solder interconnects 114, and/or (x) a second board interconnect from the plurality of board interconnects 112.

A third electrical path between the integrated device 107 and the integrated device 103 may include (i) a third wire bond from the plurality of wire bonds 170, (ii) a third plurality of interconnects from the plurality of interconnects 162, (iii) a third solder interconnect from the plurality of solder interconnects 161, (iv) a third plurality of interconnects from the plurality of interconnects 142, (v) a third solder interconnect from the plurality of solder interconnects 174, (vi) an inner interconnect (e.g., wire) from a second inter substrate interconnect structure (e.g., 105), (vii) a third solder interconnect from the plurality of solder interconnects 172, (viii) a third plurality of interconnects from the plurality of interconnects 122, (ix) a first solder interconnect from the plurality of solder interconnects 132, and/or (x) a first pillar interconnect from the plurality of pillar interconnects 130.

A fourth electrical path between the integrated device 107 and the integrated device 103 may include (i) a fourth wire bond from the plurality of wire bonds 170, (ii) a fourth plurality of interconnects from the plurality of interconnects 162, (iii) a fourth solder interconnect from the plurality of solder interconnects 161, (iv) a fourth plurality of interconnects from the plurality of interconnects 142, (v) a fourth solder interconnect from the plurality of solder interconnects 174, (vi) an outer interconnect (e.g., a non-wire interconnect) from the second inter substrate interconnect structure (e.g., 105), (vii) a fourth solder interconnect from the plurality of solder interconnects 172, (viii) a fourth plurality of interconnects from the plurality of interconnects 122, (ix) a second solder interconnect from the plurality of solder interconnects 132, and/or (x) a second pillar interconnect from the plurality of pillar interconnects 130.

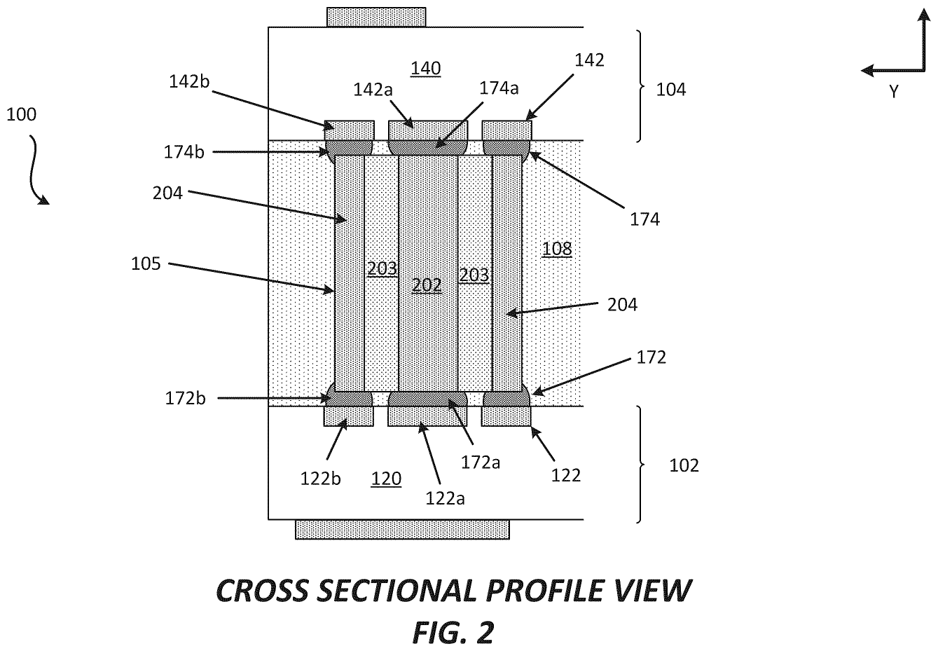

More specific examples of inter substrate interconnect structures are further described below in at least FIGS. 2-10, including examples of inner interconnects and outer interconnects.

FIG. 2 illustrates a close up view of the package 100 that includes an inter substrate interconnect structure 105. The inter substrate interconnect structure 105 includes a wire 202, a dielectric layer 203 and an interconnect 204. The wire 202 may be an example of an inner interconnect for the inter substrate interconnect structure 105. Thus, it will be noted that the inter substrate interconnect structure 105 is not limited to the use of a wire for the wire 202. The wire 202 may be replaced with other types of interconnects, such as an electroplated interconnect to be an inner interconnect for any of the inter substrate interconnect structures described in the disclosure. In another example the wire 202 may be replaced with a pin (e.g., pin wire). The interconnect 204 may be an example of an outer interconnect for the inter substrate interconnect structure 105. The interconnect 204 may be a non-wire interconnect. A non-wire interconnect is an interconnect is an interconnect that is not formed through a wire drawing process. The wire 202 may be different from the interconnect 204. For example, the wire 202 may include a different material from the interconnect 204. The wire 202 may have a different composition from the interconnect 204. In some implementations, the wire 202 may have a similar or the same composition as the plurality of wire bonds 170. The wire 202 may include gold (Au), Aluminum (Al) and/or copper (Cu). The dielectric layer 203 may laterally surround the wire 202. The interconnect 204 may laterally surround the dielectric layer 203 and the wire 202. The dielectric layer 203 may be located between the wire 202 and the interconnect 204. The dielectric layer 203 may include polyimide or silicon nitride. The interconnect 204 may include a ring interconnect (e.g., outer ring interconnect). The wire 202 (e.g., inner interconnect) may have a cylinder shape.

Different implementations may have different components of the inter substrate interconnect structure 105. In some implementations, the inter substrate interconnect structure 105 comprises a structure width (e.g., structure diameter) of about 160-180 micrometers. In some implementations, the wire 202 (which is an example of an inner interconnect) comprises a width (e.g., wire width) of about 35-45 micrometers. In some implementations, the interconnect 204 comprises a wall interconnect width of about 35-45 micrometers. For example, the thickness of the wall interconnect of the interconnect 204 (e.g., in the Y direction) may be about 35-45 micrometers. In some implementations, the dielectric layer 203 may be about 20-30 micrometers. For example, the space between the wire 202 and the interconnect 204 may be about 20-30 micrometers.

The plurality of interconnects 122 includes an interconnect 122a and an interconnect 122b. The interconnect 122a (e.g., first interconnect) may include a pad interconnect. The interconnect 122a may have a concentric planar cross section (e.g., concentric ring planar cross section, ring planar cross section). The interconnect 122b (e.g., second interconnect) may include a pad interconnect. The interconnect 122a may have a ring planar cross section. The plurality of interconnects 142 includes an interconnect 142a and an interconnect 142b. The interconnect 142a (e.g., first interconnect) may include a pad interconnect. The interconnect 142a may have a concentric planar cross section. The interconnect 142b (e.g., second interconnect) may include a pad interconnect. The interconnect 142a may have a ring planar cross section. In FIG. 2, the planar cross section may be located along and/or parallel to an X-Y plane.

The plurality of solder interconnects 172 includes a solder interconnect 172a and a solder interconnect 172b. The plurality of solder interconnects 174 includes a solder interconnect 174a and a solder interconnect 174b. The solder interconnect 172a is coupled to and touching a first end portion of the wire 202 and the interconnect 122a. The solder interconnect 174a is coupled to and touching a second end portion of the wire 202 and the interconnect 142a. The solder interconnect 172b is coupled to and touching a first end portion of the interconnect 204 and the interconnect 122b. The solder interconnect 174b is coupled to and touching a second end portion of the interconnect 204 and the interconnect 142b.

The inter substrate interconnect structure 105 is configured to provide a first electrical path and a second electrical path. A first electrical between the substrate 102 and the substrate 104 may include the interconnect 122a, the solder interconnect 172a, the wire 202 (e.g., inner interconnect) of the inter substrate interconnect structure 105, a solder interconnect 174a and the interconnect 142a. A second electrical between the substrate 102 and the substrate 104 may include the interconnect 122b, the solder interconnect 172b, the interconnect 204 (e.g., outer interconnect) of the inter substrate interconnect structure 105, a solder interconnect 174b and the interconnect 142b. The inter substrate interconnect structure 105 may be configured as a coaxial interconnect structure.

In some implementations, a power or signal is configured to travel through the wire 202, and ground is configured to travel through the interconnect 204. In some implementations, the interconnect 204 is configured to provide shielding (e.g., electromagnetic interference shield) for power or signal traveling through the wire 202. In some implementations, ground is configured to travel through the wire 202, and a power or signal is configured to travel through the interconnect 204.

There are many advantages to the plurality of inter substrate interconnect structures 105. One, the use of the plurality of inter substrate interconnect structures 105 may help increase the number of electrical paths between substrates, which can help increase the performance of the package and/or the integrated device. Two, the use of the plurality of inter substrate interconnect structures 105 may help decrease the size and/or form factor of the package, since more interconnects and/or electrical paths can be provided for a given region. Three, the use of the plurality of inter substrate interconnect structures 105 may help reduce cross talks due to the shielding that is provided, which helps provide better signal quality. Four, the use of the plurality of inter substrate interconnect structures 105 may help optimizes the power distribution network for the package.

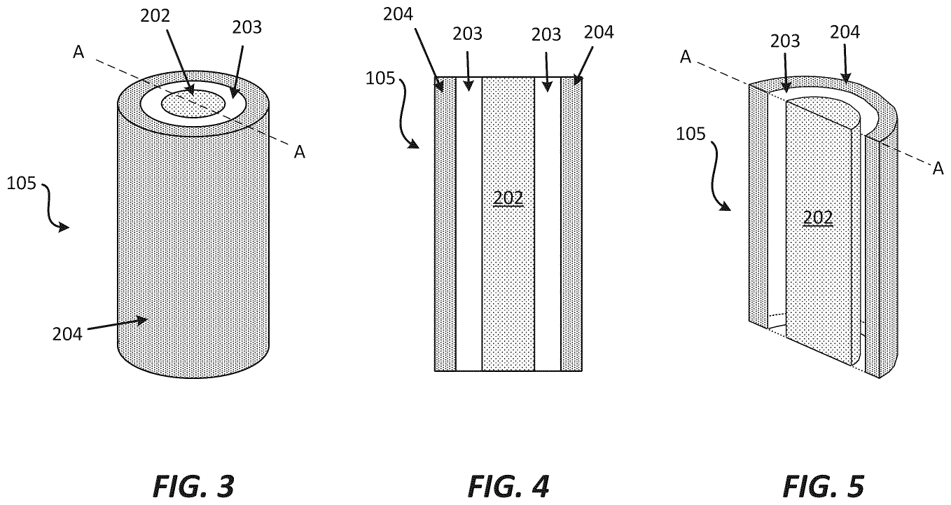

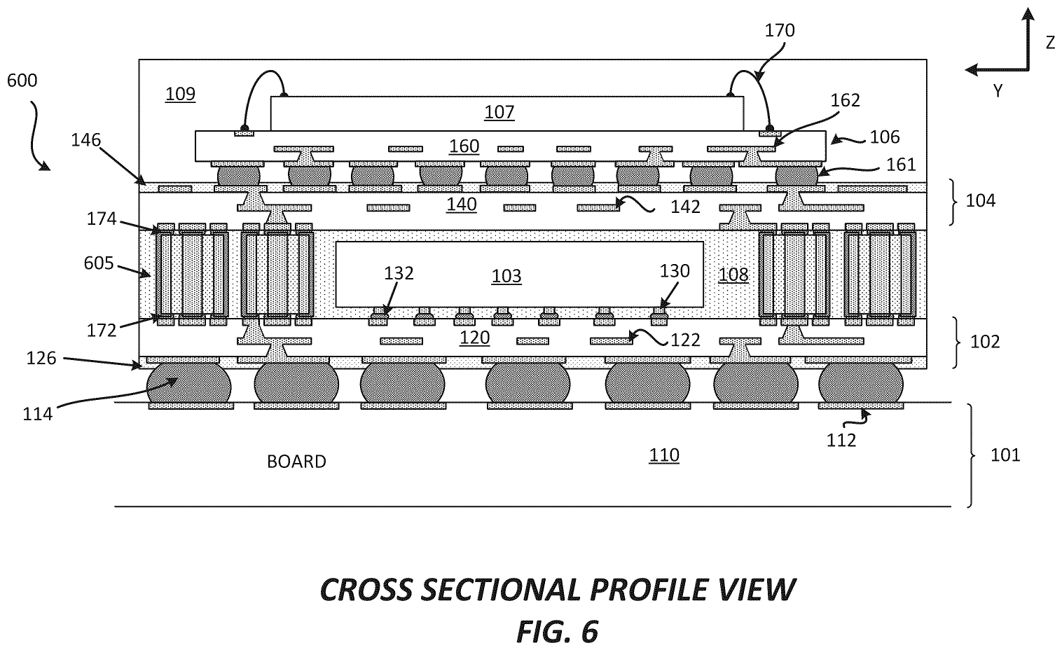

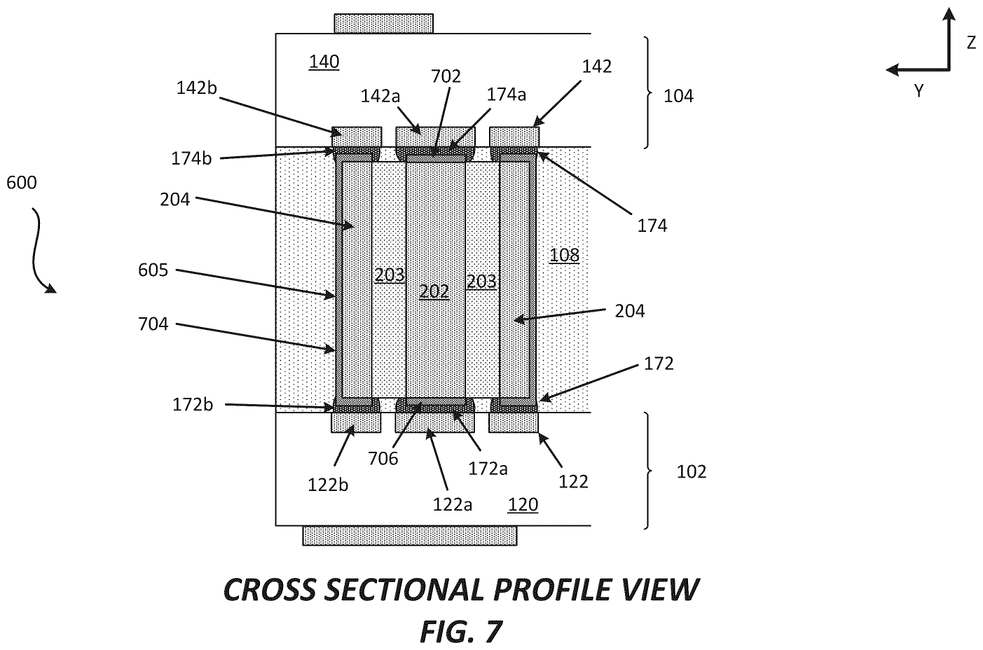

FIGS. 3-5 illustrate exemplary views of an inter substrate interconnect structure 105. FIG. 3 illustrates an angled view of the inter substrate interconnect structure 105. FIG. 4 illustrates a cross sectional view of the inter substrate interconnect structure 105 across the AA cross section. FIG. 5 illustrates another cross sectional view of the inter substrate interconnect structure 105 across the AA cross section. The inter substrate interconnect structure 105 is configured to provide a first electrical path and a second electrical path. The inter substrate interconnect structure 105 include the wire 202 (e.g., inner interconnect), the dielectric layer 203 and the interconnect 204 (e.g., outer interconnect, outer ring interconnect). The dielectric layer 203 may surround and touch the wire 202. The interconnect 204 may surround and touch the dielectric layer 203. The interconnect 204 may surround the wire 202, but does not touch the wire 202. The interconnect 204 may be a non-wire interconnect. The wire 202 may have the shape of a cylinder and/or a concentric planar cross section (e.g., circular planar cross section). The interconnect 204 may have a ring planar cross section. A first electrical path may include the wire 202. A second electrical path may include the interconnect 204. The interconnect 204 may be configured as a shield (e.g., electromagnetic interference shield) for a current traveling through the wire 202.

Different implementations may have different configurations of an inter substrate interconnect structure.

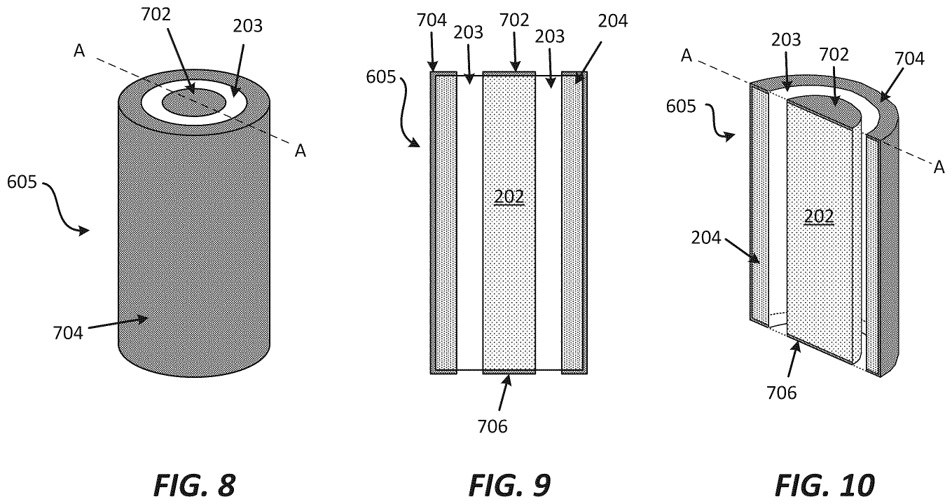

FIG. 6 illustrates a cross sectional profile view of a package 600 that includes inter substrate interconnect structures comprising a wire. The package 600 may be implemented as part of a package on package (POP). The package 600 is coupled to a board 101 through a plurality of solder interconnects 114. The board 101 includes at least one board dielectric layer 110 and a plurality of board interconnects 112. The board 101 may include a printed circuit board (PCB).

The package 600 is similar to the package 100 and include similar components as the package 100. The components of the package 600 may be arranged in a similar manner as the components of the package 100. The package 600 includes a plurality of inter substrate interconnect structures 605.

The package 900 includes a substrate 102, an integrated device 103, a substrate 104, a substrate 106, an integrated device 107, an encapsulation layer 108, an encapsulation layer 109 and a plurality of inter substrate interconnect structures 605. As will be further described below, each of inter substrate interconnect structures 605 may include a protection layer. The inter substrate interconnect structure 605 may be configured as a coaxial interconnect structure.

The integrated device 103 is coupled to the substrate 102 through at least a plurality of solder interconnects 132. For example, the integrated device 103 is coupled to a plurality of interconnects 121 of the substrate 102 through a plurality of pillar interconnects 130 and/or a plurality of solder interconnects 132. The substrate 102 includes a dielectric layer 120, a plurality of interconnects 122 and a solder resist layer 126. The substrate 102 is coupled to the board 101 through the plurality of solder interconnects 114.

The plurality of inter substrate interconnect structures 105 are coupled to the plurality of interconnects 122 of the substrate 102 through a plurality of solder interconnects 172. The substrate 104 is coupled to the plurality of inter substrate interconnect structures 105 through a plurality of solder interconnects 174. The substrate 104 is coupled to the substrate 102 through the plurality of inter substrate interconnect structures 105. The encapsulation layer 108 is located between the substrate 102 and the substrate 104. The encapsulation layer 108 is coupled to the substrate 102 and the substrate 104. The encapsulation layer 108 may at least partially encapsulate the integrated device 103 and the plurality of inter substrate interconnect structures 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The substrate 104 includes a dielectric layer 140, a plurality of interconnects 142 and a solder resist layer 146. The substrate 106 includes a dielectric layer 160 and a plurality of interconnects 162. The substrate 106 is coupled to the substrate 104 through a plurality of solder interconnects 161. The integrated device 107 may be mechanically coupled to the substrate 106. An adhesive may be used to mechanically couple the integrated device 107 to the substrate 106. A plurality of wire bonds 170 are coupled to the integrated device 107 and the substrate 106. The plurality of wire bonds 170 may be coupled to pads of the integrated device 107 and the plurality of interconnects 162 of the substrate 106. The plurality of wire bonds 170 may be configured to provide electrical paths between the integrated device 107 and the substrate 106. The plurality of wire bonds 170 may include wires.

The encapsulation layer 109 may be coupled to a surface of the substrate 104. The encapsulation layer 109 may at least partially encapsulate the substrate 106, the integrated device 107 and the plurality of wire bonds 170. The encapsulation layer 109 may include a mold, a resin and/or an epoxy. The encapsulation layer 109 may be a means for encapsulation. The encapsulation layer 109 may be similar to the encapsulation layer 108. The encapsulation layer 109 may be provided by using a compression and transfer molding process, a sheet molding process, or a liquid molding process.

Each inter substrate interconnect structure from the plurality of inter substrate interconnect structures 605 may be configured to provide a first electrical path and a second electrical path. Each inter substrate interconnect from the plurality of inter substrate interconnect structures 605 may be an inter substrate concentric interconnect structure.

A first electrical path between the integrated device 107 and the board 101 may include (i) a first wire bond from the plurality of wire bonds 170, (ii) a first plurality of interconnects from the plurality of interconnects 162, (iii) a first solder interconnect from the plurality of solder interconnects 161, (iv) a first plurality of interconnects from the plurality of interconnects 142, (v) a first solder interconnect from the plurality of solder interconnects 174, (vi) an inner interconnect (e.g., wire) from an inter substrate interconnect structure (e.g., 605), (vii) a first solder interconnect from the plurality of solder interconnects 172, (viii) a first plurality of interconnects from the plurality of interconnects 122, (ix) a first solder interconnect from the plurality of solder interconnects 114, and/or (x) a first board interconnect from the plurality of board interconnects 112.

A second electrical path between the integrated device 107 and the board 101 may include (i) a second wire bond from the plurality of wire bonds 170, (ii) a second plurality of interconnects from the plurality of interconnects 162, (iii) a second solder interconnect from the plurality of solder interconnects 161, (iv) a second plurality of interconnects from the plurality of interconnects 142, (v) a second solder interconnect from the plurality of solder interconnects 174, (vi) an outer interconnect (e.g., a non-wire interconnect) from an inter substrate interconnect structure (e.g., 605), (vii) a second solder interconnect from the plurality of solder interconnects 172, (viii) a second plurality of interconnects from the plurality of interconnects 122, (ix) a second solder interconnect from the plurality of solder interconnects 114, and/or (x) a second board interconnect from the plurality of board interconnects 112.

A third electrical path between the integrated device 107 and the integrated device 103 may include (i) a third wire bond from the plurality of wire bonds 170, (ii) a third plurality of interconnects from the plurality of interconnects 162, (iii) a third solder interconnect from the plurality of solder interconnects 161, (iv) a third plurality of interconnects from the plurality of interconnects 142, (v) a third solder interconnect from the plurality of solder interconnects 174, (vi) an inner interconnect (e.g., another wire) from a second inter substrate interconnect structure (e.g., 605), (vii) a third solder interconnect from the plurality of solder interconnects 172, (viii) a third plurality of interconnects from the plurality of interconnects 122, (ix) a first solder interconnect from the plurality of solder interconnects 132, and/or (x) a first pillar interconnect from the plurality of pillar interconnects 130.

A fourth electrical path between the integrated device 107 and the integrated device 103 may include (i) a fourth wire bond from the plurality of wire bonds 170, (ii) a fourth plurality of interconnects from the plurality of interconnects 162, (iii) a fourth solder interconnect from the plurality of solder interconnects 161, (iv) a fourth plurality of interconnects from the plurality of interconnects 142, (v) a fourth solder interconnect from the plurality of solder interconnects 174, (vi) an outer interconnect (e.g., another non-wire interconnect) from the second inter substrate interconnect structure (e.g., 605), (vii) a fourth solder interconnect from the plurality of solder interconnects 172, (viii) a fourth plurality of interconnects from the plurality of interconnects 122, (ix) a second solder interconnect from the plurality of solder interconnects 132, and/or (x) a second pillar interconnect from the plurality of pillar interconnects 130.

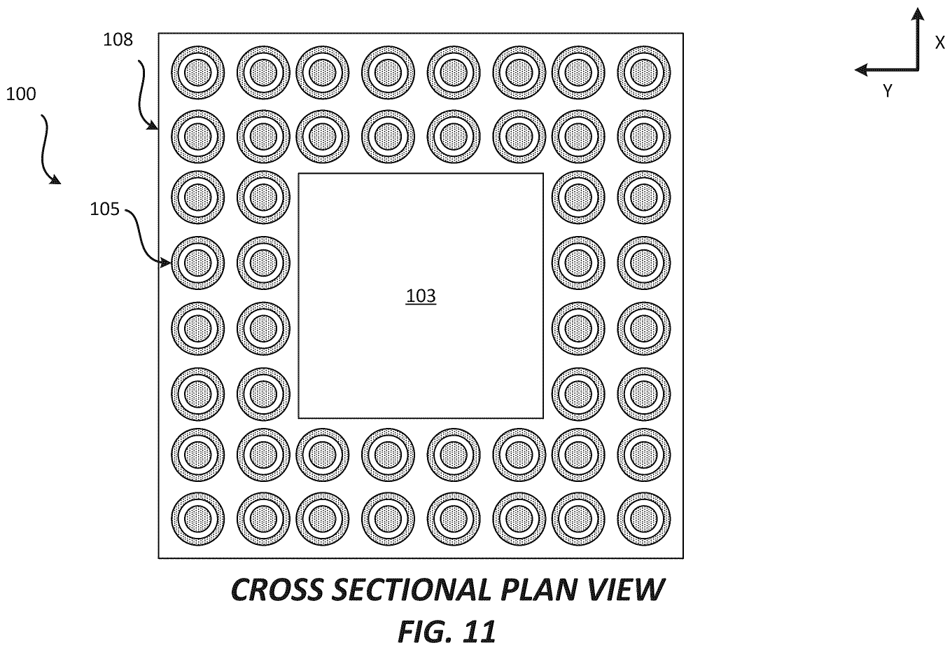

More specific examples of inter substrate interconnect structures are further described below in at least FIGS. 7-10, including examples of inner interconnects and outer interconnects.

FIG. 7 illustrates a close up view of the package 600 that includes an inter substrate interconnect structure 605. The inter substrate interconnect structure 105 includes a wire 202 (e.g., inner interconnect), a dielectric layer 203, an interconnect 204 (e.g., outer interconnect), a protection layer 702, the protection layer 704 and a protection layer 706. The interconnect 204 may be a non-wire interconnect. The wire 202 may be different from the interconnect 204. For example, the wire 202 may include a different material from the interconnect 204. The wire 202 may have a different composition from the interconnect 204. The wire 202 may have a similar or the same composition as the plurality of wire bonds 170. The wire 202 may include gold (Au), Aluminum (Al) and/or copper (Cu). The dielectric layer 203 may laterally surround the wire 202. The interconnect 204 may laterally surround the dielectric layer 203 and the wire 202. The dielectric layer 203 may be located between the wire 202 and the interconnect 204.

The protection layer 702, the protection layer 704 and the protection layer 706 may include a metal layer that is electrically conducting. For example, the protection layer 702, the protection layer 704 and the protection layer 706 may include nickel (Ni) and/or tin (Sn). The protection layer 704 may be coupled to and touch the interconnect 204. The protection layer 702 may be coupled to and touch a first end portion of the wire 202. The protection layer 706 may be coupled to and touch a second end portion of the wire 202. The wire 202 may be replaced with a pin (e.g., pin wire).

The inter substrate interconnect structure 605 is configured to provide a first electrical path and a second electrical path. A first electrical between the substrate 102 and the substrate 104 may include the interconnect 122a, the solder interconnect 172a, the protection layer 706, the wire 202 of the inter substrate interconnect structure 105, the protection layer 702, a solder interconnect 174a and the interconnect 142a. A second electrical between the substrate 102 and the substrate 104 may include the interconnect 122b, the solder interconnect 172b, the protection layer 704, the interconnect 204 of the inter substrate interconnect structure 105, the protection layer 704, a solder interconnect 174b and/or the interconnect 142b. The inter substrate interconnect structure 605 may be configured as a coaxial interconnect structure.

In some implementations, a power or signal is configured to travel through the wire 202, and ground is configured to travel through the interconnect 204. In some implementations, the interconnect 204 is configured to provide shielding (e.g., electromagnetic interference shield) for power or signal traveling through the wire 202. In some implementations, ground is configured to travel through the wire 202, and a power or signal is configured to travel through the interconnect 204.

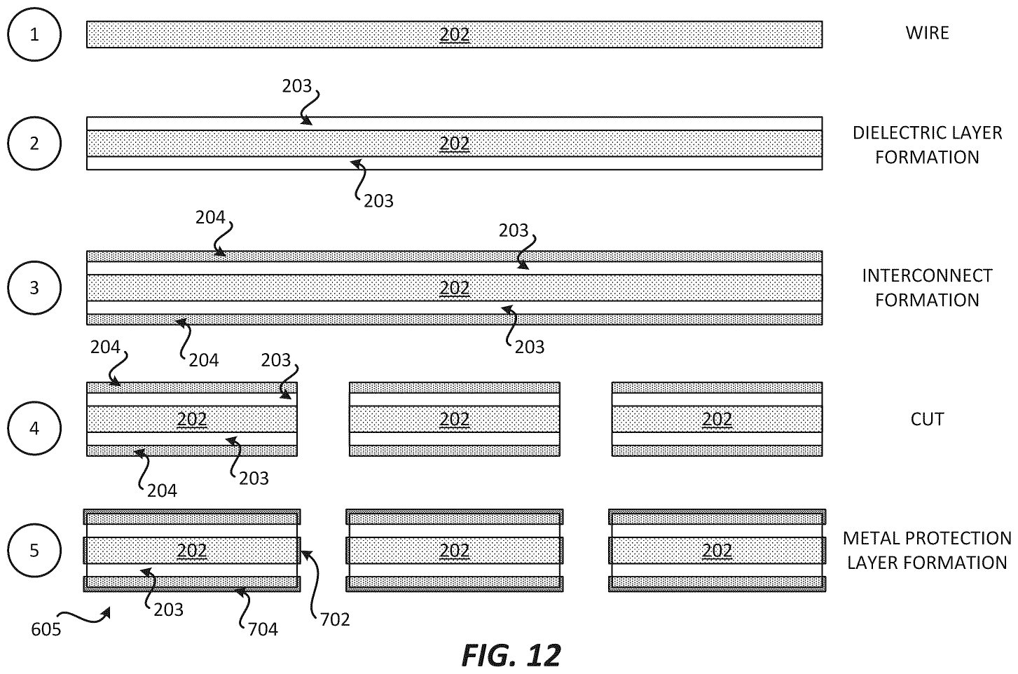

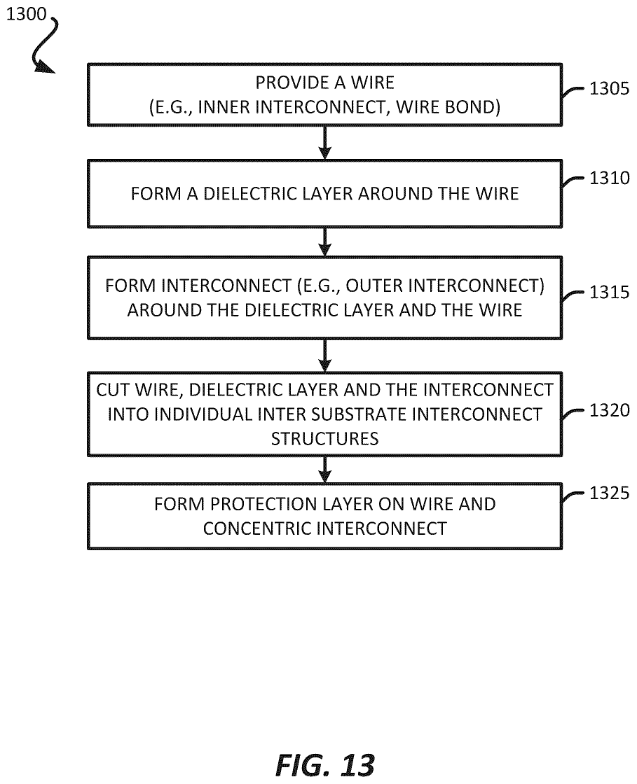

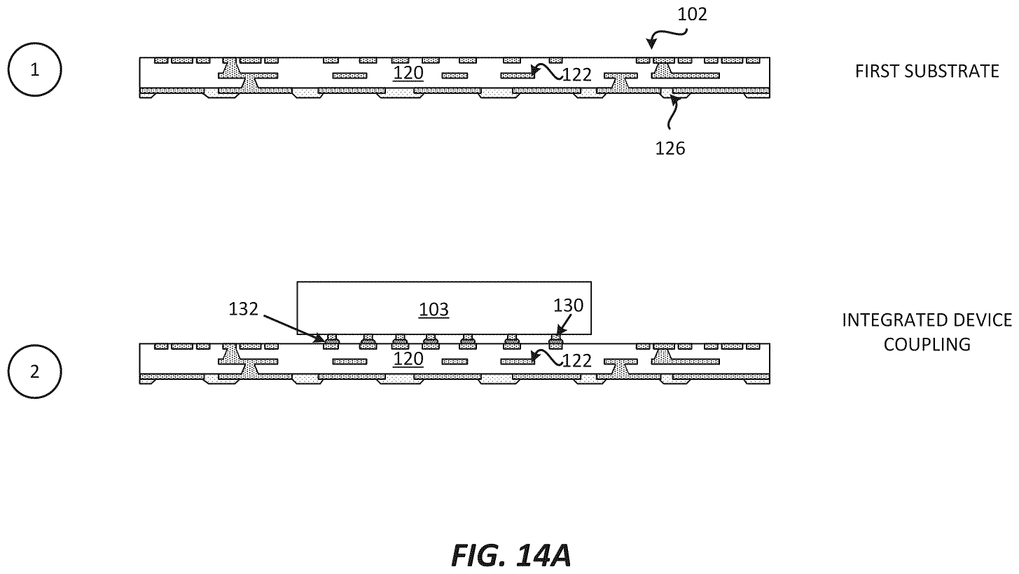

FIGS. 8-10 illustrate exemplary views of an inter substrate interconnect structure 605. FIG. 8 illustrates an angled view of the inter substrate interconnect structure 605. FIG. 9 illustrates a cross sectional view of the inter substrate interconnect structure 605 across the AA cross section. FIG. 10 illustrates another cross sectional view of the inter substrate interconnect structure 605 across the AA cross section. The inter substrate interconnect structure 605 is configured to provide a first electrical path and a second electrical path. The inter substrate interconnect structure 605 include the wire 202, the dielectric layer 203, the interconnect 204, the protection layer 702, the protection layer 704 and the protection layer 706. The dielectric layer 203 may surround and touch the wire 202. The interconnect 204 may surround and touch the dielectric layer 203. The interconnect 204 may surround the wire 202, but does not touch the wire 202. The interconnect 204 may be a non-wire interconnect. The wire 202 may have the shape of a cylinder and/or a concentric planar cross section (e.g., circular planar cross section). The interconnect 204 may have a ring planar cross section. A first electrical path may include the wire 202. A second electrical path may include the interconnect 204. The interconnect 204 may be configured as a shield (e.g., electromagnetic interference shield) for a current traveling through the wire 202.

The protection layer 702, the protection layer 704 and the protection layer 706 may include a metal layer that is electrically conducting. For example, the protection layer 702, the protection layer 704 and the protection layer 706 may include nickel (Ni) and/or tin (Sn). The protection layer 704 may be coupled to and touch the interconnect 204. The protection layer 702 may be coupled to and touch a first end portion of the wire 202. The protection layer 706 may be coupled to and touch a second end portion of the wire 202.

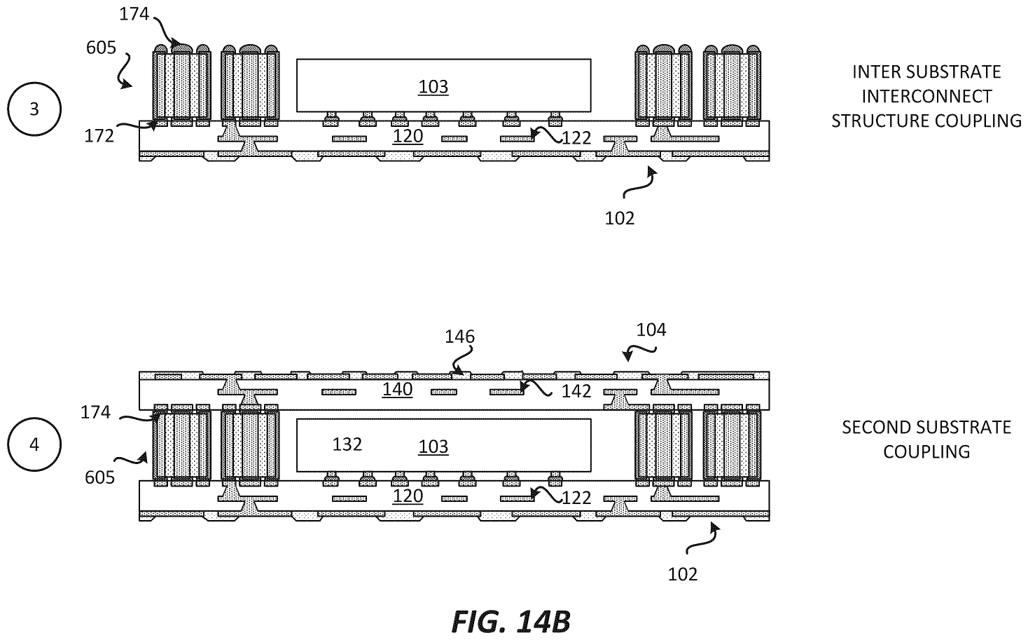

FIG. 11 illustrates an exemplary plan view of the package 100. The package 100 includes the integrated device 103, the encapsulation layer 108 and the plurality of inter substrate interconnect structures 105. In some implementations, the package 100 may include the plurality of inter substrate interconnect structures 605. The plurality of inter substrate interconnect structures 605 may replace or be used with the plurality of inter substrate interconnect structures 105 in a package. The plurality of inter substrate interconnect structures 105 laterally surround the integrated device 103. The plurality of inter substrate interconnect structures 105 may be arranged in lateral rows and/or lateral columns of inter substrate interconnect structures.

An integrated device (e.g., 103, 107) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 600) may be implemented in a radio frequency (RF) package. The RF package may be a radio frequency front end (RFFE) package. A package (e.g., 100, 600) may be configured to provide Wireless Fidelity (WiFi) communication and/or cellular communication (e.g., 2G, 3G, 4G, 5G). The packages (e.g., 100, 600) may be configured to support Global System for Mobile (GSM) Communications, Universal Mobile Telecommunications System (UMTS), and/or Long-Term Evolution (LTE). The packages (e.g., 100, 600) may be configured to transmit and receive signals having different frequencies and/or communication protocols.

### Exemplary Sequence for Fabricating an Inter Substrate Interconnect Structure

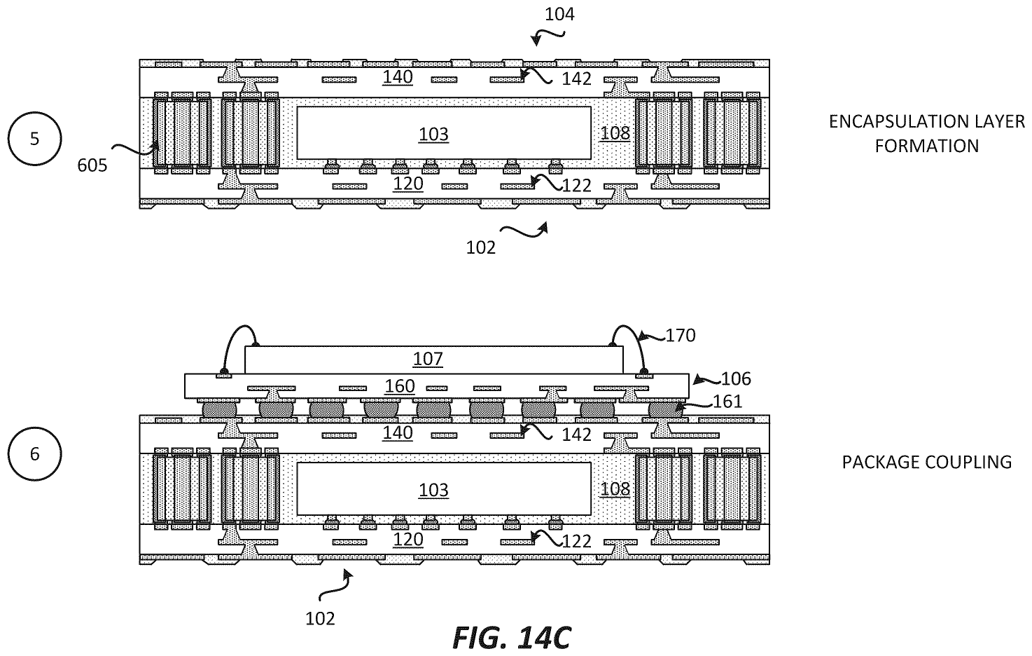

In some implementations, fabricating a substrate includes several processes. FIG. 12 illustrates an exemplary sequence for providing or fabricating an inter substrate interconnect structure. In some implementations, the sequence of FIG. 12 may be used to provide or fabricate the inter substrate interconnect structure 605. However, the process of FIG. 12 may be used to fabricate any of the inter substrate interconnect structures described in the disclosure.

It should be noted that the sequence of FIG. 12 may combine one or more stages in order to simplify and/or clarify the sequence for providing or fabricating an inter substrate interconnect structure. In some implementations, the order of the processes may be changed or modified. In some implementations, one or more of processes may be replaced or substituted without departing from the scope of the disclosure.
Stage 1 illustrates a state after a wire 202 is provided. 120 is provided. The wire may be formed through a wire drawing process. Different implementations may use different materials for the wire 202. In some implementations, the wire 202 may include gold (Au), Aluminum (Al) and/or copper (Cu). The wire 202 may be an example of an inner interconnect. Other processes may be used to form an inner interconnect that is similar and/or the same in structure and/or composition to the wire 202.
Stage 2 illustrates a state after a dielectric layer 203 is formed around the wire 202. The dielectric layer 203 may be formed along the length of the wire 202. Different implementations may use different materials for the dielectric layer 203. The dielectric layer 203 may include polyimide or silicon nitride. A deposition process and/or a lamination process may be used to form the dielectric layer 203.
Stage 3 illustrates a state after an interconnect 204 is formed and coupled to the dielectric layer 203. The interconnect 204 may be formed along the length of the wire 202 and the dielectric layer 203. The interconnect 204 may be formed around the dielectric layer 203. The interconnect 204 may include a seed layer and a metal layer. The seed layer may include copper (Cu). A sputter process may be used to form the seed layer. The metal layer may include copper (Cu). A plating process (e.g., electroplating process) may be used to form the metal layer.
Stage 4 illustrates a state after the wire 202, the dielectric layer 203 and the interconnect 204 are cut into several inter substrate interconnect structures. Stage 4 may illustrate examples of an inter substrate interconnect structure 105. A punching process may be used to cut the wire 202, the dielectric layer 203 and the interconnect 204 to form an inter substrate interconnect structure.
Stage 5 illustrates a state after protections layers are formed. The protection layer 702, the protection layer 704 and the protection layer 706 may include a metal layer that is electrically conducting. For example, the protection layer 702, the protection layer 704 and the protection layer 706 may include nickel (Ni) and/or tin (Sn). The protection layer 704 may be coupled to and touch the interconnect 204. The protection layer 702 may be coupled to and touch a first end portion of the wire 202. The protection layer 706 may be coupled to and touch a second end portion of the wire 202. A plating process (e.g., electroplating process) may be used to form the protection layer. Stage 5 may illustrate examples of an inter substrate interconnect structure 605.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating an Inter Substrate Interconnect Structure

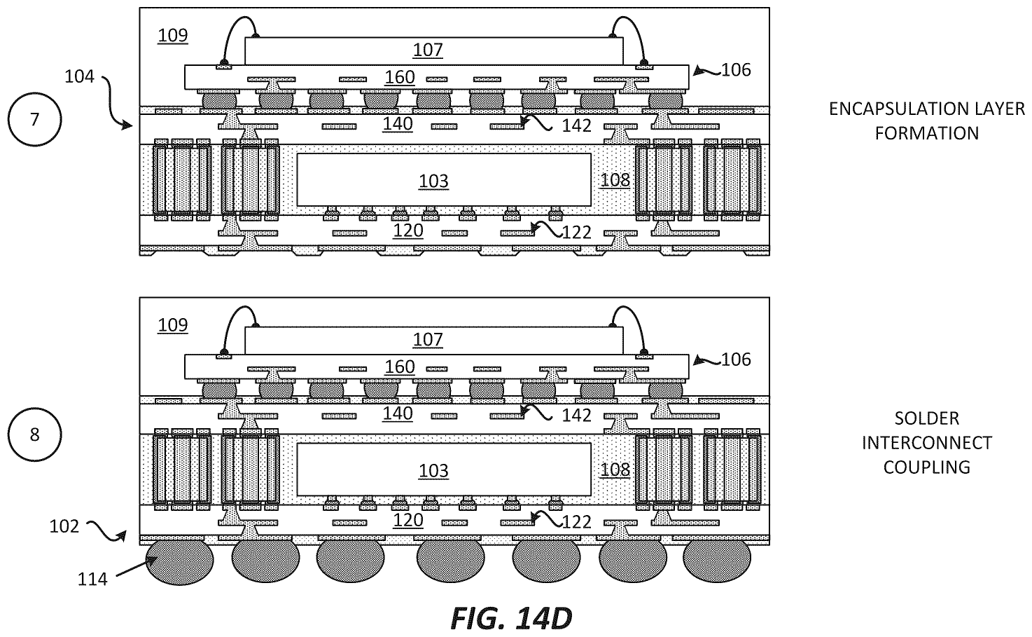

In some implementations, fabricating an inter substrate interconnect structure includes several processes. FIG. 13 illustrates an exemplary flow diagram of a method 1300 for providing or fabricating an inter substrate interconnect structure. In some implementations, the method 1300 of FIG. 13 may be used to provide or fabricate the any of an inter substrate interconnect structures of the disclosure. For example, the method 1300 of FIG. 13 may be used to fabricate the an inter substrate interconnect structure 605.

It should be noted that the method 1300 of FIG. 13 may combine one or more processes in order to simplify and/or clarify the method for providing or fabricating an inter substrate interconnect structure. In some implementations, the order of the processes may be changed or modified.

The method provides (at 1305) a wire. Stage 1 of FIG. 12, illustrates and describes an example of a state after a wire 202 is provided. 120 is provided. The wire may be formed through a wire drawing process. Different implementations may use different materials for the wire 202. The wire 202 may be an example of an inner interconnect. In some implementations, the wire 202 may include gold (Au), Aluminum (Al) and/or copper (Cu). Other processes may be used to form an inner interconnect that can replace the wire 202.

The method forms (at 1310) a dielectric layer around the wire. Stage 2 of FIG. 12, illustrates and describes an example of a state after a dielectric layer 203 is formed around the wire 202. The dielectric layer 203 may be formed along the length of the wire 202. Different implementations may use different materials for the dielectric layer 203. The dielectric layer 203 may include polyimide or silicon nitride. A deposition process and/or a lamination process may be used to form the dielectric layer 203.

The method forms (at 1315) an interconnect around the dielectric layer and the wire. The interconnect may be an outer interconnect around the dielectric layer and the wire. The interconnect may be a concentric interconnect (e.g., concentric ring interconnect, ring interconnect) around the dielectric layer and the wire. Stage 3 of FIG. 12, illustrates and describes an example of a state after an interconnect 204 is formed and coupled to the dielectric layer 203. The interconnect 204 may be formed along the length of the wire 202 and the dielectric layer 203. The interconnect 204 may be formed around the dielectric layer 203. The interconnect 204 may include a seed layer and a metal layer. The seed layer may include copper (Cu). A sputter process may be used to form the seed layer. The metal layer may include copper (Cu). A plating process (e.g., electroplating process) may be used to form the metal layer.

The method cuts (at 1320) the wire, the dielectric layer and the interconnect to form several inter substrate interconnect structures. Stage 4 of FIG. 12, illustrates and describes an example of a state after the wire 202, the dielectric layer 203 and the interconnect 204 are cut into several inter substrate interconnect structures. Stage 4 may illustrate examples of an inter substrate interconnect structure 105. A punching process may be used to cut the wire 202, the dielectric layer 203 and the interconnect 204 to form an inter substrate interconnect structure.

The method forms (at 1325) a protection layer that is coupled to the wire and the interconnect. Stage 5 of FIG. 12, illustrates and describes an example of a state after protections layers are formed. The protection layer 702, the protection layer 704 and the protection layer 706 may include a metal layer that is electrically conducting. For example, the protection layer 702, the protection layer 704 and the protection layer 706 may include nickel (Ni) and/or tin (Sn). The protection layer 704 may be coupled to and touch the interconnect 204. The protection layer 702 may be coupled to and touch a first end portion of the wire 202. The protection layer 706 may be coupled to and touch a second end portion of the wire 202. A plating process (e.g., electroplating process) may be used to form the protection layer. Stage 5 may illustrate examples of an inter substrate interconnect structure 605.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package Comprising Inter Substate Interconnect Structures Comprising an Inner Interconnect

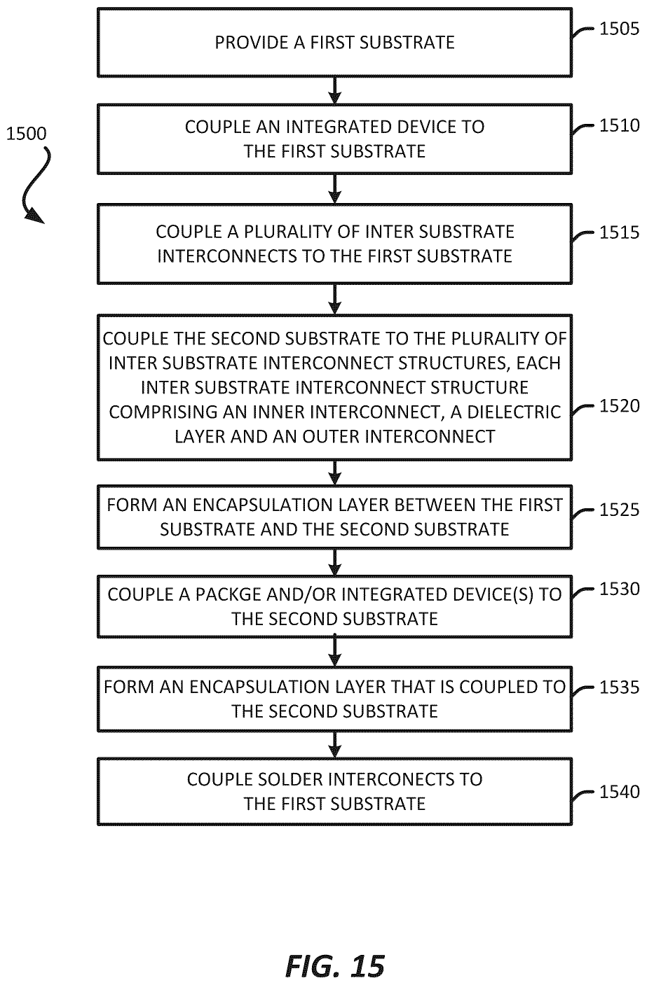

In some implementations, fabricating a package includes several processes. FIGS. 14A-14D illustrate an exemplary sequence for providing or fabricating a package.

In some implementations, the sequence of FIGS. 14A-14D may be used to provide or fabricate the package 600. However, the process of FIGS. 14A-14D may be used to fabricate any of the packages (e.g., 100) described in the disclosure.

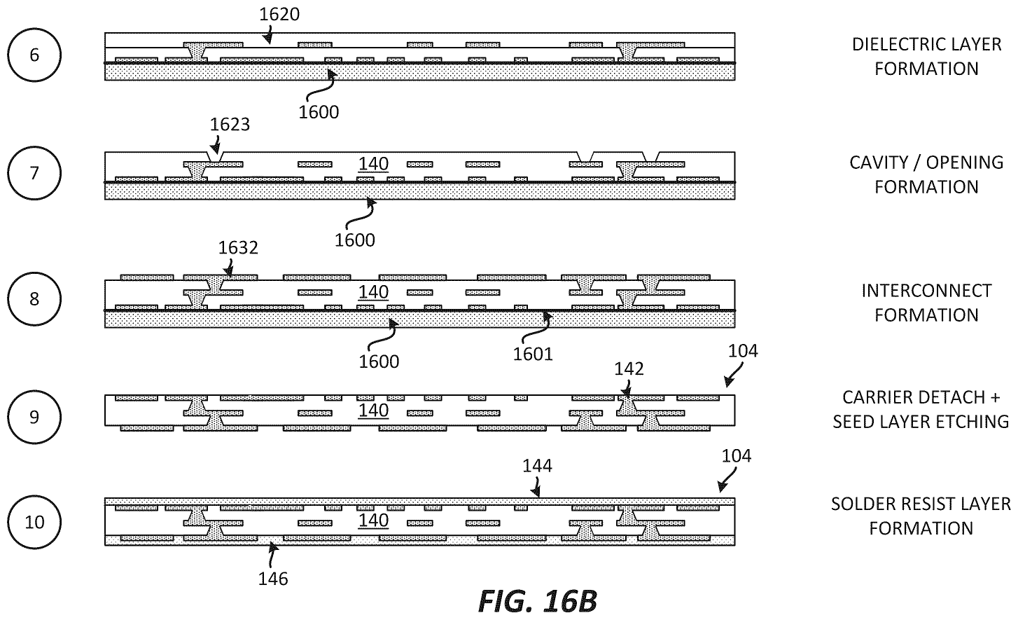

It should be noted that the sequence of FIGS. 14A-14D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.
Stage 1, as shown in FIG. 14A, illustrates a state after a substrate 102 is provided. The substrate 102 may be a first substrate. The substrate 102 includes at least one dielectric layer 120 and a plurality of interconnects 122. The substrate 102 may include a first surface (e.g., top surface) and a second surface (e.g., bottom surface). The substrate 912 may include solder resist layers. The substrate 102 may be fabricated using the method as described in FIGS. 16A-16B.
Stage 2 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.
Stage 3, as shown in FIG. 14B, illustrates a state after a plurality of inter substrate interconnect structures 605 are coupled to the substrate 102. The plurality of inter substrate interconnect structures 605 may be coupled to the plurality of interconnects 122 of the substrate 102 through a plurality of solder interconnects 172. The plurality of inter substrate interconnect structures 605 may be located laterally to the integrated device 103. A solder reflow process may be used to couple the plurality of inter substrate interconnect structures 605 to the substrate 102.
Stage 4 illustrates a state after a substrate 104 is provided and coupled to the substrate 102 through the plurality of inter substrate interconnect structures 605. The substrate 104 includes at least one dielectric layer 140 and a plurality of interconnects 142. The substrate 104 may be coupled to the plurality of inter substrate interconnect structure 605 through a plurality of solder interconnects 174. The plurality of inter substrate interconnect structures 605 may be coupled to the plurality of interconnects 142 of the substrate 104 through a plurality of solder interconnects 174. A solder reflow process may be used to couple the substrate 104 to the plurality of inter substrate interconnect structures 605. The substrate 104 may be fabricated using the method as described in FIGS. 16A-16B.
Stage 5, as shown in FIG. 14C, illustrates a state after an encapsulation layer 108 is provided between the substrate 102 and the substrate 104. The encapsulation layer 108 may at least partially encapsulate the integrated device 103 and the plurality of inter substrate interconnect structures 605. The encapsulation layer 108 may be located between the substrate 102 and the substrate 104. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.
Stage 6 illustrates a state after a package that includes a substrate 106 and the integrated device 107 are coupled to the substrate 104 through a plurality of solder interconnects 161. The integrated device 107 is mechanically coupled to the substrate 106. An adhesive (not shown) may be used to mechanically couple the integrated device 107 to the substrate 106. The substrate 106 includes at least one dielectric layer 140 and a plurality of interconnects 162. The integrated device 107 is configured to be electrically coupled to the substrate 106 through a plurality of wire bonds 170. The substrate 106 is coupled to the substrate 104 through the plurality of solder interconnects 161. A solder reflow process may be used to couple the substrate 106 to the substrate 104 through the plurality of solder interconnects 161.
Stage 7, as shown in FIG. 14D, illustrates a state after an encapsulation layer 109 is provided and coupled to the substrate 104. The encapsulation layer 109 may at least partially encapsulate the integrated device 107 and the substrate 106. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process.
Stage 8 illustrates a state after a plurality of solder interconnects 114 are coupled to the second surface of the substrate 102. A solder reflow process may be used to couple the plurality of solder interconnects 114 to the substrate 102. Stage 8 may illustrate the package 600.

### Exemplary Flow Diagram of a Method for Fabricating a Package Comprising Inter Substate Interconnect Structures Comprising an Inner Interconnect

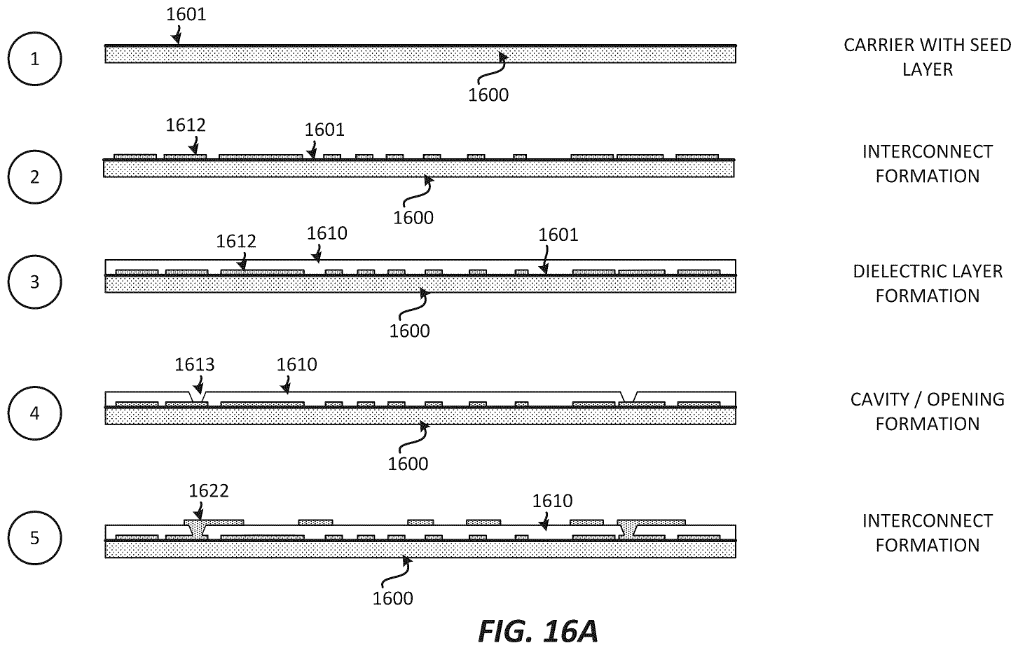

In some implementations, fabricating a package includes several processes. FIG. 15 illustrates an exemplary flow diagram of a method 1500 for providing or fabricating a package. In some implementations, the method 1500 of FIG. 15 may be used to provide or fabricate the package 600 described in the disclosure. However, the method 1500 may be used to provide or fabricate any of the packages (e.g., 100) described in the disclosure.

It should be noted that the method 1500 of FIG. 15 may combine one or more processes in order to simplify and/or clarify the method for providing or fabricating a package. In some implementations, the order of the processes may be changed or modified.

The method provides (at 1505) a first substrate. Stage 1 of FIG. 14A, illustrates and describes an example of a state after a substrate 102 is provided. The substrate 102 may be a first substrate. The substrate 102 includes at least one dielectric layer 120 and a plurality of interconnects 122. The substrate 102 may include a first surface (e.g., top surface) and a second surface (e.g., bottom surface). The substrate 912 may include solder resist layers. The substrate 102 may be fabricated using the method as described in FIGS. 16A-16B.

The method couples (at 1510) an integrated device to the first substrate. Stage 2 of FIG. 14A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

The method couples (at 1515) a plurality of inter substrate interconnect structures to the first substrate. Stage 3 of FIG. 14B, illustrates and describes an example of a state after a plurality of inter substrate interconnect structures 605 are coupled to the substrate 102. The plurality of inter substrate interconnect structures 605 may be coupled to the plurality of interconnects 122 of the substrate 102 through a plurality of solder interconnects 172. The plurality of inter substrate interconnect structures 605 may be located laterally to the integrated device 103. A solder reflow process may be used to couple the plurality of inter substrate interconnect structures 605 to the substrate 102.

The method couples (at 1520) a second substrate to the plurality of inter substrate interconnect structures. Stage 4 of FIG. 14B, illustrates and describes an example of a state after a substrate 104 is provided and coupled to the substrate 102 through the plurality of inter substrate interconnect structures 605. The substrate 104 includes at least one dielectric layer 140 and a plurality of interconnects 142. The substrate 104 may be coupled to the plurality of inter substrate interconnect structure 605 through a plurality of solder interconnects 174. The plurality of inter substrate interconnect structures 605 may be coupled to the plurality of interconnects 142 of the substrate 104 through a plurality of solder interconnects 174. A solder reflow process may be used to couple the substrate 104 to the plurality of inter substrate interconnect structures 605. The substrate 104 may be fabricated using the method as described in FIGS. 16A-16B.

The method forms (at 1525) an encapsulation layer between the first substrate and the second substrate. Stage 5 of FIG. 14C, illustrates and describes an example of a state after an encapsulation layer 108 is provided between the substrate 102 and the substrate 104. The encapsulation layer 108 may at least partially encapsulate the integrated device 103 and the plurality of inter substrate interconnect structures 605. The encapsulation layer 108 may be located between the substrate 102 and the substrate 104. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process.

The method couples (at 1530) a package and/or an integrated device to the second substrate. Stage 6 of FIG. 14C, illustrates and describes an example of a state after a package that includes a substrate 106 and the integrated device 107 are coupled to the substrate 104 through a plurality of solder interconnects 161. The integrated device 107 is mechanically coupled to the substrate 106. An adhesive (not shown) may be used to mechanically couple the integrated device 107 to the substrate 106. The substrate 106 includes at least one dielectric layer 140 and a plurality of interconnects 162. The integrated device 107 is configured to be electrically coupled to the substrate 106 through a plurality of wire bonds 170. The substrate 106 is coupled to the substrate 104 through the plurality of solder interconnects 161. A solder reflow process may be used to couple the substrate 106 to the substrate 104 through the plurality of solder interconnects 161.

The method forms (at 1535) an encapsulation layer that is coupled to the second substrate. Stage 7 of FIG. 14D, illustrates and describes an example of a state after an encapsulation layer 109 is provided and coupled to the substrate 104. The encapsulation layer 109 may at least partially encapsulate the integrated device 107 and the substrate 106. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process.

The method couples (at 1540) a plurality of solder interconnects to the first substrate. Stage 8 of FIG. 14D, illustrates and describes an example of a state after a plurality of solder interconnects 114 are coupled to the second surface of the substrate 102. A solder reflow process may be used to couple the plurality of solder interconnects 114 to the substrate 102. Stage 8 may illustrate the package 600.

### Exemplary Sequence for Fabricating a Substrate

In some implementations, fabricating a substrate includes several processes. FIGS. 16A-16B illustrate an exemplary sequence for providing or fabricating a substrate. In some implementations, the sequence of FIGS. 16A-16B may be used to provide or fabricate the substrate 104. However, the process of FIGS. 16A-16B may be used to fabricate any of the substrates (e.g., 102) described in the disclosure.

It should be noted that the sequence of FIGS. 16A-16B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.
Stage 1, as shown in FIG. 16A, illustrates a state after a carrier 1600 is provided. A seed layer 1601 may be located over the carrier 1600.
Stage 2 illustrates a state after a plurality of interconnects 1612 are formed. The interconnects 1612 may be located over the seed layer 1601. A lithography process, a plating process, a strip process and/or an etching process may be used to form the plurality of interconnects 1612. The interconnects 1612 may represent at least some of the interconnects from the plurality of interconnects 942.
Stage 3 illustrates a state after a dielectric layer 1610 is formed over the carrier 1600, the seed layer 1601 and the plurality of interconnects 1612. A deposition and/or lamination process may be used to form the dielectric layer 1610. The dielectric layer 1610 may include prepreg and/or polyimide. The dielectric layer 1610 may include a photo-imageable dielectric. However, different implementations may use different materials for the dielectric layer.
Stage 4 illustrates a state after a plurality of cavities 1613 is formed in the dielectric layer 1610. The plurality of cavities 1613 may be formed using an etching process (e.g., photo etching process), a laser process, an exposure process and/or a development process.
Stage 5 illustrates a state after interconnects 1622 are formed in and over the dielectric layer 1610, including in and over the plurality of cavities 1613. For example, a via, pad and/or traces may be formed. A lithography process, a plating process, a strip process and/or an etching process may be used to form the interconnects.
Stage 6, as shown in FIG. 16B, illustrates a state after a dielectric layer 1620 is formed over the dielectric layer 1610 and the plurality of interconnects 1622. A deposition and/or lamination process may be used to form the dielectric layer 1620. The dielectric layer 1620 may include prepreg and/or polyimide. The dielectric layer 1620 may include a photo-imageable dielectric. However, different implementations may use different materials for the dielectric layer.
Stage 7, illustrates a state after a plurality of cavities 1623 is formed in the dielectric layer 140. The dielectric layer 140 may represent the dielectric layer 1610 and/or the dielectric layer 1620. The plurality of cavities 1623 may be formed using an etching process (e.g., photo etching process), a laser process, an exposure process and/or a development process.
Stage 8 illustrates a state after interconnects 1632 are formed in and over the dielectric layer 140, including in and over the plurality of cavities 1623. For example, a via, pad and/or traces may be formed. A lithography process, a plating process, a strip process and/or an etching process may be used to form the interconnects.
Stage 9 illustrates a state after the carrier 1600 is decoupled (e.g., detached, removed, grinded out) from at least one dielectric layer 140 and the seed layer 1601, portions of the seed layer 1601 are removed (e.g., etched out), leaving the substrate 102 that includes at least one dielectric layer 140 and the plurality of interconnects 142. The plurality of interconnects 142 may represent the plurality of interconnects 1612, the plurality of interconnects 1622 and/or the plurality of interconnects 1632.

Stage 10 illustrates a state after the solder resist layer 144 is formed over the first surface of the substrate 104, and after the solder resist layer 146 is formed over the second surface of the substrate 104. A deposition process and/or lamination process may be used to form the solder resist layer 144 and/or the solder resist layer 146. The solder resist layer 144 and/or the solder resist layer 146 may include openings. An etching process, an exposure process and/or a development process may be used to form the openings in the solder resist layer 144 and/or the openings in the solder resist layer 146.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

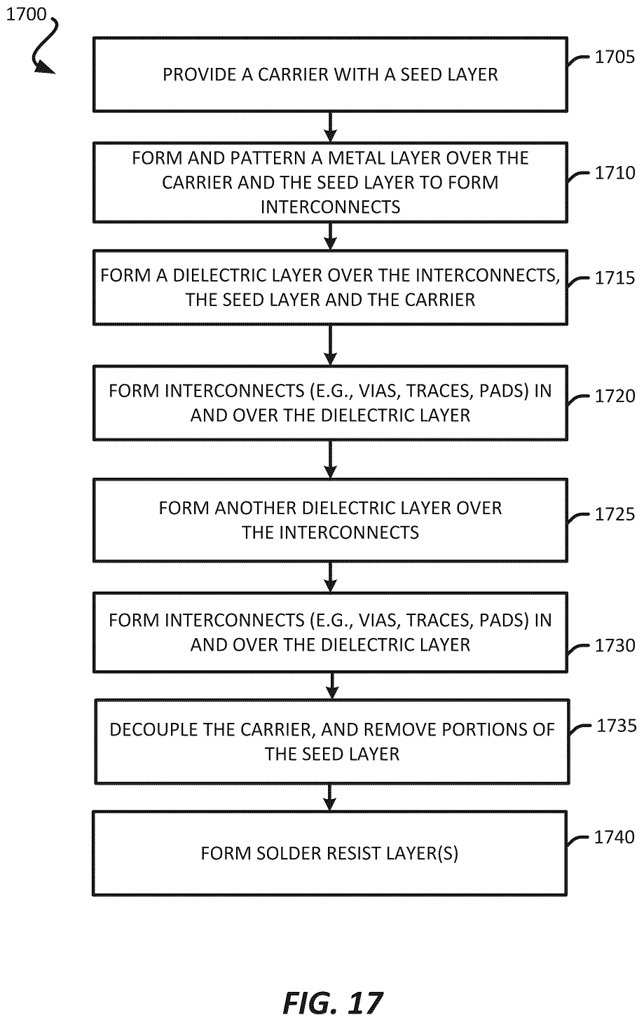

In some implementations, fabricating a substrate includes several processes. FIG. 17 illustrates an exemplary flow diagram of a method 1700 for providing or fabricating a substrate. In some implementations, the method 1700 of FIG. 17 may be used to provide or fabricate the substrate(s) of the disclosure. For example, the method 1700 of FIG. 17 may be used to fabricate the substrate 104.

It should be noted that the method 1700 of FIG. 17 may combine one or more processes in order to simplify and/or clarify the method for providing or fabricating a substrate. In some implementations, the order of the processes may be changed or modified.

The method provides (at 1705) a carrier with a seed layer. Stage 1 of FIG. 16A, illustrates and describes an example of a state after a carrier 1600 is provided. A seed layer 1601 may be located over the carrier 1600.

The method forms and patterns (at 1710) a plurality of interconnects. Stage 2 of FIG. 16A, illustrates and describes an example of a state after a plurality of interconnects 1612 are formed. The interconnects 1612 may be located over the seed layer 1601. A lithography process, a plating process, a strip process and/or an etching process may be used to form the plurality of interconnects 1612. The interconnects 1612 may represent at least some of the interconnects from the plurality of interconnects 142.

The method forms (at 1716) a dielectric layer. Stage 3 of FIG. 16A, illustrates and describes an example of a state after a dielectric layer 1610 is formed over the carrier 1600, the seed layer 1601 and the plurality of interconnects 1612. A deposition and/or lamination process may be used to form the dielectric layer 1610. The dielectric layer 1610 may include prepreg and/or polyimide. The dielectric layer 1610 may include a photo-imageable dielectric. However, different implementations may use different materials for the dielectric layer.

The method forms (at 1720) a plurality of interconnects. Forming a plurality of interconnects may including forming a plurality of cavities in a dielectric layer and a performing a plating process. Stage 4 of FIG. 16A, illustrates and describes an example of a state after a plurality of cavities 1613 is formed in the dielectric layer 1610. The plurality of cavities 1613 may be formed using an etching process (e.g., photo etching process), a laser process, an exposure process and/or a development process.
Stage 5 of FIG. 16A, illustrates and describes an example of a state after interconnects 1622 are formed in and over the dielectric layer 1610, including in and over the plurality of cavities 1613. For example, a via, pad and/or traces may be formed. A lithography process, a plating process, a strip process and/or an etching process may be used to form the interconnects.

The method forms (at 1725) another dielectric layer. Stage 6 of FIG. 16B, illustrates and describes an example of a state after a dielectric layer 1620 is formed over the dielectric layer 1610 and the plurality of interconnects 1622. A deposition and/or lamination process may be used to form the dielectric layer 1620. The dielectric layer 1620 may include prepreg and/or polyimide. The dielectric layer 1620 may include a photo-imageable dielectric. However, different implementations may use different materials for the dielectric layer.

The method forms (at 1730) a plurality of interconnects. Forming a plurality of interconnects may including forming a plurality of cavities in a dielectric layer and a performing a plating process. Stage 7 of FIG. 16B, illustrates and describes an example of a state after a plurality of cavities 1623 is formed in the dielectric layer 140. The dielectric layer 140 may represent the dielectric layer 1610 and/or the dielectric layer 1620. The plurality of cavities 1623 may be formed using an etching process (e.g., photo etching process), a laser process, an exposure process and/or a development process.
Stage 8 of FIG. 16B, illustrates and describes an example of a state after interconnects 1632 are formed in and over the dielectric layer 140, including in and over the plurality of cavities 1623. For example, a via, pad and/or traces may be formed. A lithography process, a plating process, a strip process and/or an etching process may be used to form the interconnects.

The method decouples (at 1735) a carrier. Stage 9 of FIG. 16B, illustrates and describes an example of a state after the carrier 1600 is decoupled (e.g., detached, removed, grinded out) from at least one dielectric layer 140 and the seed layer 1601, portions of the seed layer 1601 are removed (e.g., etched out), leaving the substrate 102 that includes at least one dielectric layer 140 and the plurality of interconnects 142. The plurality of interconnects 142 may represent the plurality of interconnects 1612, the plurality of interconnects 1622 and/or the plurality of interconnects 1632.

The method forms (at 1740) solder resist layers. Stage 10 of FIG. 16B, illustrates and describes an example of a state after the solder resist layer 144 is formed over the first surface of the substrate 104, and after the solder resist layer 146 is formed over the second surface of the substrate 104. A deposition process and/or lamination process may be used to form the solder resist layer 144 and/or the solder resist layer 146. An etching process, an exposure process and/or a development process may be used to form the openings in the solder resist layer 144 and/or the openings in the solder resist layer 146.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

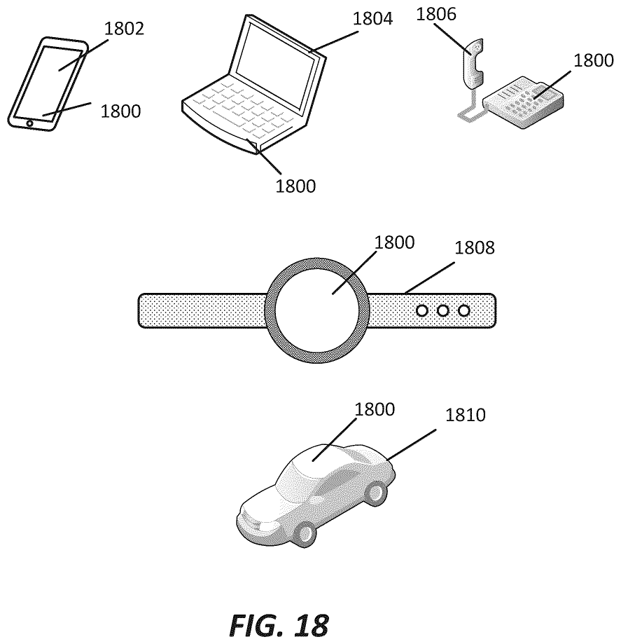

FIG. 18 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1802, a laptop computer device 1804, a fixed location terminal device 1806, a wearable device 1808, or automotive vehicle 1810 may include a device 1800 as described herein. The device 1800 may be, for example, any of the devices and/or integrated circuit (IC) packages described herein. The devices 1802, 1804, 1806 and 1808 and the vehicle 1810 illustrated in FIG. 18 are merely exemplary. Other electronic devices may also feature the device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-13, 14A-14D, 15, 16A-16B, and 17-18 may be rearranged and/or combined into a single component, process, feature or function or embodied in several components, processes, or functions. Additional elements, components, processes, and/or functions may also be added without departing from the disclosure. It should also be noted FIGS. 1-13, 14A-14D, 15, 16A-16B, and 17-18 and its corresponding description in the present disclosure is not limited to dies and/or ICs. In some implementations, FIGS. 1-13, 14A-14D, 15, 16A-16B, and 17-18 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a first substrate; an integrated device coupled to the first substrate through at least a first plurality of solder interconnects; an inter substrate interconnect structure coupled to the first substrate through at least a second plurality of solder interconnects, wherein the inter substrate interconnect structure comprises: an inner interconnect; a dielectric layer coupled to the inner interconnect; and an interconnect coupled to the dielectric layer, wherein the interconnect surrounds the dielectric layer and the inner interconnect; a second substrate coupled to the inter substrate interconnect structure through at least a third plurality of solder interconnects; and an encapsulation layer coupled to the first substrate and the second substrate.
Aspect 2: The package of aspect 1, wherein the second plurality of solder interconnects comprises a first solder interconnect and a second solder interconnect, wherein the third plurality of solder interconnects comprises a third solder interconnect and a fourth solder interconnect, wherein the first solder interconnect is coupled to the first substrate and the inner interconnect of the inter substrate interconnect structure, wherein the second solder interconnect is coupled to the first substrate and the interconnect of the inter substrate interconnect structure, wherein the third solder interconnect is coupled to the second substrate and the inner interconnect of the inter substrate interconnect structure, and wherein the fourth solder interconnect is coupled to the second substrate and the interconnect of the inter substrate interconnect structure.
Aspect 3: The package of aspects 1 through 2, wherein the inter substrate interconnect structure comprises an inter substrate concentric interconnect structure.
Aspect 4: The package of aspects 1 through 3, wherein the inner interconnect comprises a wire or a pin.
Aspect 5: The package of aspects 1 through 4, wherein the inner interconnect is configured to provide a first electrical path between the first substrate and the second substrate.
Aspect 6: The package of aspect 5, wherein the interconnect is configured to provide a second electrical path between the first substrate and the second substrate.
Aspect 7: The package of aspect 6, wherein the first electrical path is configured as an electrical path for signal or power between the first substrate and the second substrate.
Aspect 8: The package of aspect 7, wherein the second electrical path is configured as an electrical path for ground between the first substrate and the second substrate.
Aspect 9: The package of aspects 1 through 8, wherein the inter substrate interconnect structure further comprises a first protection layer coupled to the interconnect; a second protection layer coupled to a first end portion of the inner interconnect; and a third protection layer coupled to a second end portion of the inner interconnect.
Aspect 10: The package of aspect 9, wherein the first protection layer, the second protection layer and/or the third protection layer includes a different material from the inner interconnect and/or the interconnect.
Aspect 11: The package of aspects 9 through 10, wherein the inner interconnect comprises gold (Au), Aluminum (Al) and/or copper (Cu), wherein the interconnect comprises copper (Cu), and wherein the first metal layer, the second metal layer and/or the third metal layer comprises nickel (Ni) and/tin (Sn).
Aspect 12: The package of aspects 1 through 11, wherein the inter substrate interconnect structure comprises a structure width of about 160-180 micrometers, wherein the inner interconnect comprises a width of about 35-45 micrometers, wherein the interconnect comprises an interconnect width of about 35-45 micrometers, and wherein a space between the inner interconnect and the interconnect is about 20-30 micrometers.
Aspect 13: The package of aspects 1 through 12, further comprising a second integrated device coupled to the second substrate.
Aspect 14: The package of aspects 1 through 13, wherein the interconnect of the inter substrate interconnect structure comprises a ring interconnect that surrounds the inner interconnect.
Aspect 15: The package of aspects 1 through 14, further comprising a plurality of inter substrate interconnect structures, wherein the inter substrate interconnect structure is part of the plurality of inter substrate interconnect structure; wherein the plurality of inter substrate interconnect structures are coupled to the first substrate through at least the second plurality of solder interconnects, and wherein the plurality of inter substrate interconnect structures are coupled to the second substrate through at least the third plurality of solder interconnects.
Aspect 16: A method for fabricating package. The method provides a first substrate. The method couples an integrated device to the first substrate through at least a first plurality of solder interconnects. The method couples an inter substrate interconnect structure coupled to the first substrate through at least a second plurality of solder interconnects, wherein the inter substrate interconnect structure comprises an inner interconnect; a dielectric layer coupled to the inner interconnect; and an interconnect coupled to the dielectric layer, wherein the interconnect surrounds the dielectric layer and the inner interconnect. The method couples a second substrate to the inter substrate interconnect structure through at least a third plurality of solder interconnects. The method forms an encapsulation layer between the first substrate and the second substrate.
Aspect 17: The method of aspect 16, wherein the second plurality of solder interconnects comprises a first solder interconnect and a second solder interconnect, wherein the third plurality of solder interconnects comprises a third solder interconnect and a fourth solder interconnect, wherein the first solder interconnect is coupled to the first substrate and the inner interconnect of the inter substrate interconnect structure, wherein the second solder interconnect is coupled to the first substrate and the interconnect of the inter substrate interconnect structure, wherein the third solder interconnect is coupled to the second substrate and the inner interconnect of the inter substrate interconnect structure, and wherein the fourth solder interconnect is coupled to the second substrate and the interconnect of the inter substrate interconnect structure.
Aspect 18: The method of aspects 16 through 17, wherein the inter substrate interconnect structure comprises an inter substrate concentric interconnect structure, wherein the inner interconnect is configured to provide a first electrical path between the first substrate and the second substrate, and wherein the interconnect is configured to provide a second electrical path between the first substrate and the second substrate.
Aspect 19: The method of aspect 18, wherein the first electrical path is configured as an electrical path for signal or power between the first substrate and the second substrate, and wherein the second electrical path is configured as an electrical path for ground between the first substrate and the second substrate.
Aspect 20: The method of aspects 16 through 19, wherein the inter substrate interconnect structure further comprises a first protection layer coupled to the interconnect; a second protection layer coupled to a first end portion of the inner interconnect; and a third protection layer coupled to a second end portion of the inner interconnect.
Aspect 21: The package of aspects 1 through 15, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
an integrated device coupled to the first substrate through at least a first plurality of solder interconnects;
an inter substrate interconnect structure coupled to the first substrate through at least a second plurality of solder interconnects, wherein the inter substrate interconnect structure comprises:
an inner interconnect;
a dielectric layer coupled to the inner interconnect; and
an interconnect coupled to the dielectric layer, wherein the interconnect surrounds the dielectric layer and the inner interconnect;
a second substrate coupled to the inter substrate interconnect structure through at least a third plurality of solder interconnects; and
an encapsulation layer coupled to the first substrate and the second substrate.

2. The package of claim 1,
wherein the second plurality of solder interconnects comprises a first solder interconnect and a second solder interconnect,
wherein the third plurality of solder interconnects comprises a third solder interconnect and a fourth solder interconnect,
wherein the first solder interconnect is coupled to the first substrate and the inner interconnect of the inter substrate interconnect structure,
wherein the second solder interconnect is coupled to the first substrate and the interconnect of the inter substrate interconnect structure,
wherein the third solder interconnect is coupled to the second substrate and the inner interconnect of the inter substrate interconnect structure, and
wherein the fourth solder interconnect is coupled to the second substrate and the interconnect of the inter substrate interconnect structure.

3. The package of claim 1, wherein the inter substrate interconnect structure comprises an inter substrate concentric interconnect structure.

4. The package of claim 1, wherein the inner interconnect comprises a wire or a pin.

5. The package of claim 1, wherein the inner interconnect is configured to provide a first electrical path between the first substrate and the second substrate.

6. The package of claim 5, wherein the interconnect is configured to provide a second electrical path between the first substrate and the second substrate.

7. The package of claim 6, wherein the first electrical path is configured as an electrical path for signal or power between the first substrate and the second substrate.

8. The package of claim 7, wherein the second electrical path is configured as an electrical path for ground between the first substrate and the second substrate.

9. The package of claim 1, wherein the inter substrate interconnect structure further comprises:
a first protection layer coupled to the interconnect;
a second protection layer coupled to a first end portion of the inner interconnect; and
a third protection layer coupled to a second end portion of the inner interconnect.

10. The package of claim 9, wherein the first protection layer, the second protection layer and/or the third protection layer includes a different material from the inner interconnect and/or the interconnect.

11. The package of claim 9,
wherein the inner interconnect comprises gold (Au), Aluminum (Al) and/or copper (Cu),
wherein the interconnect comprises copper (Cu), and
wherein the first metal layer, the second metal layer and/or the third metal layer comprises nickel (Ni) and/tin (Sn).

12. The package of claim 1,
wherein the inter substrate interconnect structure comprises a structure width of about 160-180 micrometers,
wherein the inner interconnect comprises a width of about 35-45 micrometers,
wherein the interconnect comprises an interconnect width of about 35-45 micrometers, and
wherein a space between the inner interconnect and the interconnect is about 20-30 micrometers.

13. The package of claim 1, further comprising a second integrated device coupled to the second substrate.

14. The package of claim 1, wherein the interconnect of the inter substrate interconnect structure comprises a ring interconnect that surrounds the inner interconnect.

15. The package of claim 1, further comprising a plurality of inter substrate interconnect structures,
wherein the inter substrate interconnect structure is part of the plurality of inter substrate interconnect structures;
wherein the plurality of inter substrate interconnect structures are coupled to the first substrate through at least the second plurality of solder interconnects, and
wherein the plurality of inter substrate interconnect structures are coupled to the second substrate through at least the third plurality of solder interconnects.

16. A method for fabricating package, comprising:
providing a first substrate;
coupling an integrated device to the first substrate through at least a first plurality of solder interconnects;
coupling an inter substrate interconnect structure to the first substrate through at least a second plurality of solder interconnects, wherein the inter substrate interconnect structure comprises:
an inner interconnect;
a dielectric layer coupled to the inner interconnect; and
an interconnect coupled to the dielectric layer, wherein the interconnect surrounds the dielectric layer and the inner interconnect;
coupling a second substrate to the inter substrate interconnect structure through at least a third plurality of solder interconnects; and
forming an encapsulation layer between the first substrate and the second substrate.

17. The method of claim 16,
wherein the second plurality of solder interconnects comprises a first solder interconnect and a second solder interconnect,
wherein the third plurality of solder interconnects comprises a third solder interconnect and a fourth solder interconnect,
wherein the first solder interconnect is coupled to the first substrate and the inner interconnect of the inter substrate interconnect structure,
wherein the second solder interconnect is coupled to the first substrate and the interconnect of the inter substrate interconnect structure,
wherein the third solder interconnect is coupled to the second substrate and the inner interconnect of the inter substrate interconnect structure, and
wherein the fourth solder interconnect is coupled to the second substrate and the interconnect of the inter substrate interconnect structure.

18. The method of claim 16,
wherein the inter substrate interconnect structure comprises an inter substrate concentric interconnect structure,
wherein the inner interconnect is configured to provide a first electrical path between the first substrate and the second substrate, and
wherein the interconnect is configured to provide a second electrical path between the first substrate and the second substrate.

19. The method of claim 18,
wherein the first electrical path is configured as an electrical path for signal or power between the first substrate and the second substrate, and
wherein the second electrical path is configured as an electrical path for ground between the first substrate and the second substrate.

20. The method of claim 16, wherein the inter substrate interconnect structure further comprises:
a first protection layer coupled to the interconnect;
a second protection layer coupled to a first end portion of the inner interconnect; and
a third protection layer coupled to a second end portion of the inner interconnect.
